(19) United States
(12) Patent Application Publication
(10) Pub. No.: US 2026/0096107 A1
(43) Pub. Date: Apr. 2, 2026

(54) 1S1R-BASED SELF-SELECTIVE MEMORY AND MANUFACTURING METHOD THEREFOR

(71) Applicant: PEKING UNIVERSITY, Beijing (CN)

(72) Inventors: Zongwei WANG, Beijing (CN); Yimao CAI, Beijing (CN); Gaoqi YANG, Beijing (CN); Ru HUANG, Beijing (CN)

(73) Assignee: PEKING UNIVERSITY, Beijing (CN)

(21) Appl. No.: 19/344,073

(22) Filed: Sep. 29, 2025

(30) Foreign Application Priority Data
Sep. 30, 2024 (CN) 202411391881.4
Oct. 11, 2024 (CN) 202411419563.4

(51) Int. Cl. H10B 63/00; H10N 70/00; H10N 70/20

(52) U.S. Cl. CPC H10B 63/20; H10N 70/043; H10N 70/20; H10N 70/826; H10N 70/8822; H10N 70/8825; H10N 70/8828; H10N 70/8833; H10N 70/8836; H10N 70/884

(57) ABSTRACT

The present disclosure relates to a 1S1R-based self-selective memory, a manufacturing method therefor, and an electronic device. An intermediate layer is arranged between a selector layer and a resistive switching layer. The thermal conductivity of the intermediate layer is lower than that of the resistive switching layer. The intermediate layer is arranged between the resistive switching layer and the selector layer.

### RELATED APPLICATIONS

This application claims priority to Chinese patent application No. 202411419563.4, filed on Oct. 11, 2024, entitled “1S1R-BASED SELF-SELECTIVE MEMORY AND MANUFACTURING METHOD THEREFOR, AND DEVICE”, and Chinese patent application No. 202411391881.4, filed on Sep. 30, 2024, entitled “1S1R-BASED SELF-SELECTIVE MEMORY AND MANUFACTURING METHOD THEREFOR, AND DEVICE”, the entire contents of which are hereby incorporated by reference in its entirety.

### TECHNICAL FIELD

The present disclosure relates to the field of integrated circuit technology, and in particular to a 1S1R-based self-selective memory and a manufacturing method therefor, and an electronic device.

### BACKGROUND

Resistive Random Access Memory (RRAM) has characteristics of simple structure, small feature size, and fast programming/erasing speed, showing great development potential. At present, most RRAM uses a 1T1R architecture integrating a selector and a memristor, where the selector and the memristor together serve as a basic unit. The 1T1R architecture has a relatively large feature size, which limits the scalability of RRAM and is not conducive to three-dimensional integration.

### SUMMARY

In a first aspect, a 1S1R-based self-selective memory is provided in the present disclosure. The 1S1R-based self-selective memory includes a first functional layer, an intermediate layer, and a second functional layer, which are sequentially stacked on a substrate. The second functional layer is separated from the first functional layer by the intermediate layer. The first functional layer is connected to a first electrode. The second functional layer is connected to a second electrode.

One of the first functional layer and the second functional layer is a selector layer. The other is a resistive switching layer. The thermal conductivity of the intermediate layer is lower than that of the resistive switching layer.

In a second aspect, a manufacturing method for a 1S1R-based self-selective memory is provided in the present disclosure. The manufacturing method for the 1S1R-based self-selective memory includes the following steps:
providing a substrate, and forming a first electrode on the substrate;
forming a first functional layer on the first electrode;
forming an intermediate layer on the first functional layer;
forming a second functional layer on the intermediate layer, wherein the second functional layer is separated from the first functional layer by the intermediate layer; one of the first functional layer and the second functional layer is a selector layer, and the other is a resistive switching layer; the thermal conductivity of the intermediate layer is lower than that of the resistive switching layer;
forming a second electrode on the second functional layer.

In a third aspect, an electronic device is provided in the present disclosure. The electronic device includes the 1S1R-based self-selective memory provided in the first aspect, or the 1S1R-based self-selective memory manufactured by the manufacturing method for the 1S1R-based self-selective memory provided in the second aspect.

### BRIEF DESCRIPTION OF DRAWINGS

To more clearly illustrate the technical solutions in the embodiments of the present disclosure or the conventional technologies, the drawings required for describing the embodiments or the conventional technologies shall be briefly introduced below. Obviously, the drawings in the following description are only some embodiments of the present disclosure. For those skilled in the art, other drawings can be obtained according to these drawings without inventive effort.

FIG. 1 is a schematic structural diagram of a 1S1R-based self-selective memory provided in an embodiment.

FIG. 2 is a schematic structural diagram of a 1S1R-based self-selective memory provided in another embodiment.

FIG. 3 is a process flowchart of a manufacturing method for a 1S1R-based self-selective memory provided in an embodiment.

### DETAILED DESCRIPTION

For ease of understanding the present disclosure, the present disclosure will be described more comprehensively below with reference to the relevant drawings. Preferred embodiments of the present disclosure are shown in the drawings. However, the present disclosure can be implemented in many different forms and is not limited to the embodiments described herein. On the contrary, the purpose of providing these embodiments is to disclose the present disclosure more comprehensively.

Unless otherwise defined, all technical and scientific terms used herein have the same meanings as those commonly understood by those skilled in the art. The terms used in the specification of the present disclosure are only for the purpose of describing specific embodiments and are not intended to limit the present disclosure.

RRAM, with a 1S1R architecture (using a selector and a memristor together to serve as a basic unit), integrating the selector (as a threshold switching device) and the memristor, has a smaller feature size. By utilizing the threshold transition characteristic of the selector, a leakage current on the RRAM in low resistance in an unselected cell can be suppressed. A 1S1R unit composed of a selector and a resistive random access memory is not only suitable for storage but also for implementing neuromorphic computing systems. However, RRAM with the 1S1R architecture still has many problems that limit its application.

Accordingly, it is necessary to provide a 1S1R-based self-selective memory, a manufacturing method therefor, and an electronic device, to address the problem that the RRAM with the 1S1R architecture in the related art is limited in application.

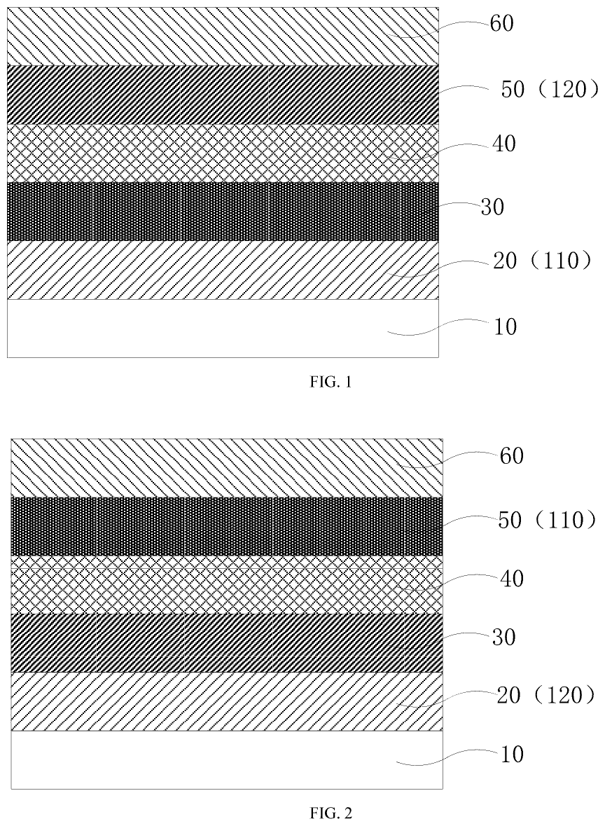

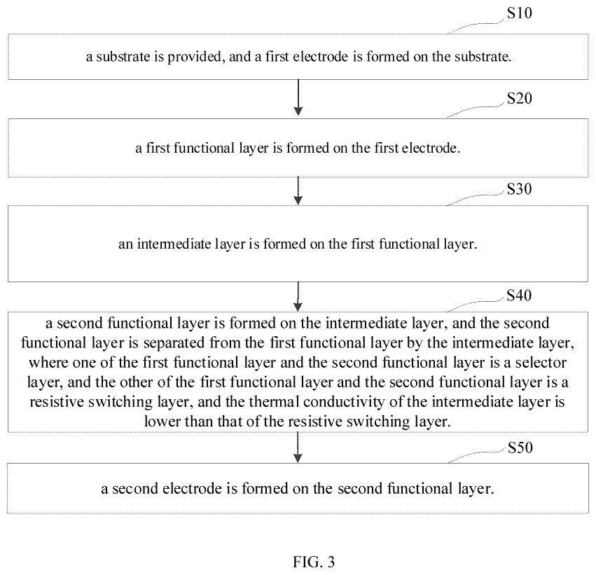

In an embodiment, a 1S1R-based self-selective memory is provided. Referring to FIG. 1 and FIG. 2, the self-selective memory includes a first functional layer 30, an intermediate layer 40, and a second functional layer 50, which are sequentially stacked on a substrate 10. The second functional layer 50 is separated from the first functional layer 30 by the intermediate layer 40. The first functional layer 30 is connected to a first electrode 20. The first electrode 20 is arranged between the substrate 10 and the first functional layer 30. The second functional layer 50 is connected to a second electrode 60. One of the first functional layer 30 and the second functional layer 50 is a selector layer 110, and the other is a resistive switching layer 120. The thermal conductivity of the intermediate layer 40 is lower than that of the resistive switching layer 120.

In the 1S1R-based self-selective memory of this embodiment, the intermediate layer 40 is provided between the selector layer 110 and the resistive switching layer 120. Firstly, since the thermal conductivity of the intermediate layer 40 is lower than that of the resistive switching layer 120, and the intermediate layer 40 is provided between the resistive switching layer 120 and the selector layer 110, the heat transferring from the selector layer 110 to the resistive switching layer 120 can be impeded, so that the temperature of the selector layer 110 can rapidly rise to a turn-on temperature. This can reduce the turn-on voltage (Vth) of the self-selective memory, enabling the self-selective memory to achieve self-selective storage. At the same time, the intermediate layer 40 can improve the thermal stability of the selector layer 110, delay the temperature drop of the selector layer 110, and reduce the overall writing voltage and reading voltage of the self-selective memory. Secondly, the intermediate layer 40 can also avoid performance degradation of the self-selective memory caused by the mutual diffusion of materials between the selector layer 110 and the resistive switching layer 120, thus improving the reliability and performance stability of the self-selective memory.

In the 1S1R-based self-selective memory of this embodiment, the intermediate layer is provided between the selector layer and the resistive switching layer, the thermal conductivity of the intermediate layer is lower than that of the resistive switching layer, and the intermediate layer is provided between the resistive switching layer and the selector layer, resulting in the heat transferring from the selector layer to the resistive switching layer can be impeded, realizing the temperature of the selector layer can rapidly rise to a turn-on temperature. This can reduce the turn-on voltage of the self-selective memory, enabling the self-selective memory to achieve self-selective storage. At the same time, the intermediate layer can improve the thermal stability of the selector layer, delay the temperature drop of the selector layer, and reduce the overall writing voltage and reading voltage of the self-selective memory. Further, the intermediate layer can also avoid performance degradation of the self-selective memory caused by the mutual diffusion of the materials between the selector layer and the resistive switching layer, thus improving the reliability and performance stability of the self-selective memory.

In an embodiment, referring to FIG. 1 and FIG. 2, the thermal conductivity of the intermediate layer 40 is higher than that of the selector layer 110. This prevents the intermediate layer 40 from affecting the temperature rise of the selector layer 110.

In an embodiment, the thermal conductivity of the selector layer 110 is in the range from 0.3 W/m·K to 1.5 W/m·K. For example, the thermal conductivity of the selector layer 110 may be 0.3 W/m·K, 0.4 W/m·K, 0.5 W/m·K, 0.6 W/m·K, 0.7 W/m·K, 0.8 W/m·K, 0.9 W/m·K, 1.0 W/m·K, 1.1 W/m·K, 1.2 W/m·K, 1.3 W/m·K, or 1.5 W/m·K.

The thermal conductivity of the resistive switching layer 120 is in the range from 2.2 W/m·K to 5 W/m·K. For example, the thermal conductivity of the resistive switching layer 120 may be 2.2 W/m·K, 2.3 W/m·K, 2.4 W/m·K, 2.5 W/m·K, 2.6 W/m·K, 2.7 W/m·K, 3 W/m·K, 3.5 W/m·K, 4 W/m·K, 4.5 W/m·K, or 5 W/m·K.

The thermal conductivity of the intermediate layer 40 is in the range from 0.2 W/m·K to 2 W/m·K. For example, the thermal conductivity of the intermediate layer 40 may be 0.2 W/m·K, 0.3 W/m·K, 0.4 W/m·K, 0.5 W/m·K, 0.6 W/m·K, 0.7 W/m·K, 0.72 W/m·K, 0.75 W/m·K, 0.8 W/m·K, 1.0 W/m·K, 1.2 W/m·K, 1.4 W/m·K, 1.5 W/m·K, 1.6 W/m·K, 1.7 W/m·K, 1.9 W/m·K, or 2.0 W/m·K.

The electrical conductivity of the intermediate layer 40 is in the range from 10⁻⁷ S/m to 10⁻² S/m. For example, the electrical conductivity of the intermediate layer 40 may be 10⁻⁷ S/m, 10⁻⁶ S/m, 10⁻⁵ S/m, 10⁻⁴ S/m, 10⁻³ S/m, or 10⁻² S/m.

With the thermal conductivity ranging from 0.2 W/m·K to 2 W/m·K and the electrical conductivity ranging from 10⁻⁷ S/m to 10⁻² S/m, the intermediate layer 40 has good electrical conductivity and certain heat insulation. Therefore, when the intermediate layer 40 is arranged between the selector layer 110 and the resistive switching layer 120, the conduction between the selector layer 110 and the resistive switching layer 120 is not affected, and the turn-on voltage of the self-selective memory can be reduced as well.

In an embodiment, referring to FIG. 1 and FIG. 2, the thermal conductivity of the side of the intermediate layer 40 close to the resistive switching layer 120 is lower than that of the side close to the selector layer 110.

The intermediate layer 40 serves as a barrier layer arranged on the selector layer 110 to prevent the heat of the selector layer 110 from spreading outward and to store the heat inside the selector layer 110. Since the thermal conductivity of the side of the intermediate layer 40 close to the selector layer 110 is higher than that of the side close to the resistive switching layer 120, it becomes more difficult for the heat generated by the selector layer 110 to spread outward through the intermediate layer 40. Thus, the temperature rise rate of the selector layer 110 is increased, allowing the selector layer 110 to quickly reach the turn-on temperature.

The thermal conductivity of the side of the intermediate layer 40 close to the resistive switching layer 120 is lower than that of the side close to the selector layer 110, and the resistive switching layer 120 can be arranged as a multi-layer structure. The fact that the thermal conductivity of the side of the intermediate layer 40 close to the resistive switching layer 120 is lower than that of the side close to the selector layer 110 can be achieved by any one or more methods, such as adjusting the component content of the material in the intermediate layer 40 or doping. For example, the thermal conductivity of the intermediate layer 40 can be adjusted by adjusting the concentration of doped ions in the intermediate layer 40.

In an embodiment, the thermal conductivity of the intermediate layer 40 decreases in the direction from the selector layer 110 to the resistive switching layer 120.

The intermediate layer 40 may include multiple layers. The multiple layers can be arranged between the selector layer 110 and the resistive switching layer 120 in a stacked manner. In the direction from the selector layer 110 to the resistive switching layer 120, the thermal conductivity of the multiple layers of the intermediate layer 40 decreases sequentially. In an embodiment, as shown in FIG. 1 and FIG. 2, the intermediate layer 40 can be a single-layer structure. Therefore, a deposition process for forming the intermediate layer 40 can also be controlled to make the material composition of the intermediate layer 40 change gradually in the direction from the selector layer 110 to the resistive switching layer 120, thereby making the thermal conductivity of the intermediate layer 40 decrease gradually.

In an example, the intermediate layer 40 includes a first intermediate sub-layer and a second intermediate sub-layer sequentially stacked in the direction from the selector layer 110 to the resistive switching layer 120. The thermal conductivity of the second intermediate sub-layer is lower than that of the first intermediate sub-layer.

In another example, the intermediate layer 40 includes a first intermediate sub-layer, a second intermediate sub-layer, and a third intermediate sub-layer, which are sequentially stacked in the direction from the selector layer 110 to the resistive switching layer 120. The thermal conductivity of the first intermediate sub-layer, the second intermediate sub-layer, and the third intermediate sub-layer decreases in sequence.

In an embodiment, the thermal conductivity of the side of the selector layer 110 close to the intermediate layer 40 is lower than that of the side far away from the intermediate layer 40. As such, in the direction from the selector layer 110 to the resistive switching layer 120, the selector layer 110 and the intermediate layer 40 form a stacked structure with gradually decreasing thermal conductivity. This can further improve the thermal stability of the selector layer 110, delay the temperature drop of the selector layer, and thus reduce the overall writing voltage and reading voltage of the self-selective memory.

In an embodiment, the selector layer 110 can be a single-layer structure, and the thermal conductivity of the selector layer 110 can be controlled by any one or more methods, such as adjusting the component content of the material in the selector layer 110 or doping.

In an embodiment, the selector layer 110 can also be a multi-layer structure, and the thermal conductivity of the selector layer 110 can be controlled by controlling the thermal conductivity of each layer in the multi-layer structure.

In an embodiment, referring to FIG. 1 and FIG. 2, the thermal conductivity of the side of the resistive switching layer 120 far away from the intermediate layer 40 is lower than that of the side of the selector layer 110 close to the intermediate layer 40. Thus, in the direction from the selector layer 110 to the resistive switching layer 120, the selector layer 110, the intermediate layer 40, and the resistive switching layer 120 together form a stacked structure with gradually decreasing thermal conductivity, which can further improve the thermal stability of the selector layer 110 and the performance of the self-selective memory.

Similarly, the resistive switching layer 120 can be a single-layer structure or a multi-layer structure.

In an embodiment, the material of the intermediate layer 40 includes at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

In an embodiment, the intermediate layer 40 can be a single-layer structure or a multi-layer structure. For example, the intermediate layer 40 may include a single amorphous carbon layer, or a stacked amorphous carbon layer and an indium gallium zinc oxide layer.

In some embodiments, the material of the intermediate layer 40 includes amorphous carbon. Amorphous carbon has good electrical conductivity, thermal conductivity, and thermal insulation. This is conducive to maintaining the temperature of the selector layer 110, improving the threshold transition characteristic of the selector layer 110, and facilitating the three-dimensional integration of the self-selective memory.

In an embodiment, the material of the selector layer 110 includes at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride.

In an embodiment, the material of the resistive switching layer 120 includes at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

As such, by reasonably selecting and matching the materials of the selector layer 110 and the resistive switching layer 120 of the self-selective memory, the self-selective memory can have a self-rectification effect. This can effectively suppress the leakage current generated by the self-selective memory, which is beneficial to further reducing the size of the self-selective memory and manufacturing the self-selective memory into an integrated array, thereby extending the applicable fields and scenarios of the self-selective memory.

For example, the material of the resistive switching layer 120 includes tantalum oxide, and the material of the selector layer 110 includes niobium oxide. This can further improve the self-rectification capability of the resistive switching memory and suppress the leakage current of the self-selective memory.

In an embodiment, a thermal conductive material is doped in the selector layer 110. The thermal conductive material is used to improve the thermal conductivity of the selector layer 110, as well as the temperature rise rate and thermal stability of the selector layer 110.

In an embodiment, the thermal conductive material may include one or more of Al, Cu, Au, Ti, and the like.

In an embodiment, the concentration of the thermal conductive material doped in the selector layer 110 can be controlled so that the thermal conductivity of the side of the selector layer 110 close to the intermediate layer 40 is lower than that of the side far away from the intermediate layer 40.

In an embodiment, the material of the first electrode 20 may include at least one of vanadium (V), niobium (Nb), ruthenium (Ru), tungsten (W), tantalum (Ta), tantalum nitride (TaN), titanium (Ti), titanium nitride (TiN), titanium tungsten (TiW), aluminum (Al), titanium aluminum tungsten (TiAlW), iridium (Ir), iridium oxide (IrO₂), indium tin oxide (ITO), titanium aluminum nitride (TiAlN), aluminum nitride (AlNₓ), hafnium (Hf), manganese (Mn), zinc (Zn), platinum (Pt), palladium (Pd), or copper (Cu). The first electrode 20 can be a single-layer structure or a multi-layer structure.

A selection range for the material of the second electrode 60 is the same as that of the first electrode 20, and will not be repeated here.

In an embodiment, the first electrode 20 and the second electrode 60 may be made of the same material or different materials.

In an embodiment, referring to FIG. 1, the first functional layer 30 is the selector layer 110, and the second functional layer 50 is the resistive switching layer 120. The material of the first functional layer 30 includes niobium oxide. The material of the intermediate layer 40 includes amorphous carbon. The material of the second functional layer 50 includes tantalum oxide. The first electrode 20, the selector layer 110, the intermediate layer 40, the resistive switching layer 120, and the second electrode 60 are sequentially stacked on the substrate 10. This can further improve the self-rectification capability of the resistive switching memory and suppress the leakage current of the self-selective memory.

In an embodiment, referring to FIG. 2, the first functional layer 30 is the resistive switching layer 120, and the second functional layer 50 is the selector layer 110. The material of the first functional layer 30 includes tantalum oxide. The material of the intermediate layer 40 includes amorphous carbon. The material of the second functional layer 50 includes niobium oxide. The first electrode 20, the resistive switching layer 120, the intermediate layer 40, the selector layer 110, and the second electrode 60 are sequentially stacked on the substrate 10. This can further improve the self-rectification capability of the resistive switching memory and suppress the leakage current of the self-selective memory.

In an embodiment, as shown in FIG. 3, a manufacturing method for a 1S1R-based self-selective memory is provided, which includes the following steps S10-S50.
Step S10: a substrate is provided, and a first electrode is formed on the substrate.
Step S20: a first functional layer is formed on the first electrode.
Step S30: an intermediate layer is formed on the first functional layer.
Step S40: a second functional layer is formed on the intermediate layer, and the second functional layer is separated from the first functional layer by the intermediate layer, where one of the first functional layer and the second functional layer is a selector layer, the other is a resistive switching layer, and the thermal conductivity of the intermediate layer is lower than that of the resistive switching layer.
Step S50: a second electrode is formed on the second functional layer.

In the manufacturing method for a 1S1R-based self-selective memory provided in this embodiment, an intermediate layer is formed between the selector layer and the resistive switching layer. Since the thermal conductivity of the intermediate layer is lower than that of the resistive switching layer, and the intermediate layer is arranged between the resistive switching layer and the selector layer, it can be achieved that the heat transferring from the selector layer to the resistive switching layer is impeded, increasing the temperature rise rate of the selector layer, so that the selector layer can quickly reach the turn-on temperature. This can reduce the turn-on voltage of the selector layer of the self-selective memory and enable the self-selective memory to realize the self-selective storage. In addition, the intermediate layer can improve the thermal stability of the selector layer, delay the temperature drop of the selector layer, and reduce the overall writing voltage and reading voltage of the self-selective memory. Moreover, the manufacturing method can also avoid the performance degradation of the self-selective memory caused by the mutual diffusion of materials between the selector layer and the resistive switching layer, thus improving the reliability and performance stability of the self-selective memory.

In Step S10, referring to FIG. 1 or FIG. 2, the substrate 10 may be a semiconductor substrate. The material of the semiconductor substrate may include silicon (Si), germanium (Ge), silicon germanium (SiGe), silicon carbide (SiC), gallium arsenide (GaAs), gallium nitride (GaN), or the like. In an embodiment, the substrate 10 may be a Silicon-On-Insulator (SOI) substrate, such as a Silicon-On-Glass (SOG) substrate or a Silicon-On-Sapphire (SOP) substrate.

In an embodiment, the first electrode 20 can be formed on the substrate 10 by deposition methods such as Physical Vapor Deposition (PVD), Chemical Vapor Deposition (CVD), Plasma Enhanced Chemical Vapor Deposition (PECVD), or Atomic Layer Deposition (ALD).

In an embodiment, the material of the first electrode 20 may include one or more of vanadium, niobium, ruthenium, tungsten, tantalum, tantalum nitride, titanium, titanium nitride, titanium tungsten, aluminum, titanium aluminum tungsten, titanium aluminum nitride, aluminum nitride, AlTiN, hafnium, iridium, manganese, zinc, platinum, palladium, copper, or alloys of the above materials. The first electrode 20 can be a single-layer structure or a multi-layer structure.

In an embodiment, the thickness of the first electrode 20 can be in the range from 10 nm to 2500 nm. For example, the thickness of the first electrode 20 may be 10 nm, 100 nm, 500 nm, 1000 nm, 1500 nm, 2000 nm, or 2500 nm.

In Step S20, referring to FIG. 1 or FIG. 2, the first functional layer 30 can be formed by processes such as PVD, CVD, PECVD, ALD, ion beam sputtering, electron beam evaporation, or thermal evaporation. The first functional layer 30 is either the selector layer 110 or the resistive switching layer 120. The first functional layer 30 can be a single-layer structure or a multi-layer structure.

In Step S30, referring to FIG. 1 or FIG. 2, the intermediate layer 40 can be formed by deposition processes such as PVD, ALD, CVD, Atmospheric Pressure CVD (APCVD), PECVD, or Low Pressure CVD (LPCVD). The intermediate layer 40 can be a single-layer structure or a multi-layer structure.

In Step S40, referring to FIG. 1 or FIG. 2, the second functional layer 50 can be formed by processes such as PVD, CVD, PECVD, ALD, ion beam sputtering, electron beam evaporation, or thermal evaporation. The second functional layer 50 is either the resistive switching layer 120 or the selector layer 110. The second functional layer 50 can be a single-layer structure or a multi-layer structure.

In an embodiment, one of the first functional layer 30 and the second functional layer 50 is the selector layer 110, and the other is the resistive switching layer 120. The thermal conductivity of the intermediate layer 40 is lower than that of the resistive switching layer 120.

In Step S50, referring to FIG. 1 or FIG. 2, the second electrode 60 is formed by deposition such as PVD, CVD, PECVD, or ALD. A selection range for the material of the second electrode 60 is the same as that of the first electrode 20, and will not be repeated here.

In an embodiment, the thickness of the second electrode 60 may be in the range from 10 nm to 2500 nm. For example, the thickness of the second electrode 60 may be 10 nm, 100 nm, 500 nm, 1000 nm, 1500 nm, 2000 nm, or 2500 nm.

In an embodiment, the thermal conductivity of the intermediate layer 40 is greater than that of the selector layer 110. This prevents the intermediate layer 40 from affecting the temperature rise of the selector layer 110.

In an embodiment, the thermal conductivity of the selector layer 110 is in the range from 0.3 W/m·K to 1.5 W/m·K. For example, the thermal conductivity of the selector layer 110 may be 0.3 W/m·K, 0.4 W/m·K, 0.5 W/m·K, 0.6 W/m·K, 0.7 W/m·K, 0.8 W/m·K, 0.9 W/m·K, 1.0 W/m·K, 1.1 W/m·K, 1.2 W/m·K, 1.3 W/m·K, or 1.5 W/m·K.

In an embodiment, the thermal conductivity of the resistive switching layer 120 is in the range from 2.2 W/m·K to 5 W/m·K. For example, the thermal conductivity of the resistive switching layer 120 may be 2.2 W/m·K, 2.3 W/m·K, 2.4 W/m·K, 2.5 W/m·K, 2.6 W/m·K, 2.7 W/m·K, 3 W/m·K, 3.5 W/m·K, 4 W/m·K, 4.5 W/m·K, or 5 W/m·K.

In an embodiment, the thermal conductivity of the intermediate layer 40 is in the range from 0.2 W/m·K to 2 W/m·K. For example, the thermal conductivity of the intermediate layer 40 may be 0.2 W/m·K, 0.3 W/m·K, 0.4 W/m·K, 0.5 W/m·K, 0.6 W/m·K, 0.7 W/m·K, 0.72 W/m·K, 0.75 W/m·K, 0.8 W/m·K, 1.0 W/m·K, 1.2 W/m·K, 1.4 W/m·K, 1.5 W/m·K, 1.6 W/m·K, 1.7 W/m·K, 1.9 W/m·K, or 2.0 W/m·K.

In an embodiment, the electrical conductivity of the intermediate layer 40 is in the range from 10⁻⁷ S/m to 10⁻² S/m. For example, the electrical conductivity of the intermediate layer 40 may be 10⁻⁷ S/m, 10⁻⁶ S/m, 10⁻⁵ S/m, 10⁻⁴ S/m, 10⁻³ S/m, or 10⁻² S/m.

In an embodiment, with the thermal conductivity ranging from 0.2 W/m·K to 2 W/m·K and the electrical conductivity ranging from 10⁻⁷ S/m to 10⁻² S/m, the intermediate layer 40 has good electrical conductivity and certain heat insulation. As such, the conduction between the selector layer 110 and the resistive switching layer 120 is not affected when the intermediate layer 40 is arranged between the selector layer 110 and the resistive switching layer 120, and the turn-on voltage of the self-selective memory can also be reduced.

In an embodiment, the thermal conductivity of the side of the intermediate layer 40 close to the resistive switching layer 120 is lower than that of the side close to the selector layer 110.

When forming the intermediate layer 40, at least two material layers can be deposited so that the thermal conductivity of the material layer of the intermediate layer 40 close to the resistive switching layer 120 is lower than that of the material layer close to the selector layer 110.

Alternatively, when forming the intermediate layer 40, ions can be doped into the intermediate layer 40. By controlling the concentration of the doped ions, the thermal conductivity of the material layer of the intermediate layer 40 close to the resistive switching layer 120 can be made lower than that of the material layer close to the selector layer 110.

In an embodiment, the thermal conductivity of the intermediate layer 40 decreases in the direction from the selector layer 110 to the resistive switching layer 120.

In an embodiment, the material of the intermediate layer 40 includes at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

For example, the material of the intermediate layer 40 may include amorphous carbon.

In an embodiment, the material of the selector layer 110 includes at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride.

In an embodiment, the material of the resistive switching layer 120 includes at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

By reasonably selecting and matching the materials of the selector layer 110 and the resistive switching layer 120 of the self-selective memory, the self-selective memory can have a self-rectification effect. This can effectively suppress the leakage current generated by the self-selective memory, which is beneficial to further reducing the size of the self-selective memory so as to form an integrated array with the self-selective memory as a basic unit, thereby extending the applicable fields and scenarios of the self-selective memory.

In an embodiment, referring to FIG. 1, the first functional layer 30 is the selector layer 110. The second functional layer 50 is the resistive switching layer 120. The material of the first functional layer 30 includes niobium oxide. The material of the intermediate layer 40 includes amorphous carbon. The material of the second functional layer 50 includes tantalum oxide.

In an embodiment, referring to FIG. 2, the first functional layer 30 is the resistive switching layer 120. The second functional layer 50 is the selector layer 110. The material of the first functional layer 30 includes tantalum oxide. The material of the intermediate layer 40 includes amorphous carbon. The material of the second functional layer 50 includes niobium oxide.

In an embodiment, when forming the selector layer 110, a thermal conductive material can be doped into the selector layer 110 to improve the thermal conductivity of the selector layer 110, as well as the temperature rise rate and thermal stability of the selector layer 110.

For example, the thermal conductive material may include one or more of Al, Cu, Au, Ti, or the like. A doping process is preferred.

For example, the thermal conductive material can be doped into the selector layer 110 by means of Ion Implantation (IMP) and/or Co-Sputter.

In an embodiment, after forming the intermediate layer 40 on the first functional layer 30, the manufacturing method further includes:
Step S60: first gas is ionized to generate plasma, and the intermediate layer 40 is processed with the plasma.

Nitrogen gas can be ionized to generate nitrogen plasma, improving the film density of the selector layer 110, facilitating the reduction of the thermal budget for forming the intermediate layer 40, and thus reducing the production cost and improving the production efficiency.

In an embodiment, an electronic device is provided. The electronic device includes the 1S1R-based self-selective memory provided in the above embodiments, or the 1S1R-based self-selective memory manufactured by the manufacturing method for the 1S1R-based self-selective memory provided in the above embodiments.

The technical features of the above embodiments can be combined arbitrarily. To make the description concise, not all possible combinations of the technical features in the above embodiments are described. However, as long as there is no contradiction in the combination of these technical features, all such combinations should be regarded as within the scope described in this specification.

The above embodiments only represent some implementations of the present disclosure. They are only used to describe the technical solutions of the present disclosure in more detail and should not be regarded as limiting the technical solutions of the present disclosure. For those skilled in the art, without departing from the inventive concept of the present disclosure, several modifications and improvements can be made on the basis of the technical solutions of the present disclosure. For the sake of conciseness, these modifications and improvements are not listed one by one, but all belong to the scope described in the specification of the present disclosure.

What is claimed is:

1. A 1S1R-based self-selective memory, comprising a first functional layer, an intermediate layer, and a second functional layer, which are sequentially stacked on a substrate, wherein the second functional layer is separated from the first functional layer by the intermediate layer, the first functional layer is connected to a first electrode, and the second functional layer is connected to a second electrode, one of the first functional layer and the second functional layer is a selector layer, the other of the first functional layer and the second functional layer is a resistive switching layer, and a thermal conductivity of the intermediate layer is lower than that of the resistive switching layer.

2. The 1S1R-based self-selective memory according to claim 1, wherein a thermal conductivity of the selector layer is in a range from 0.3 W/m·K to 1.5 W/m·K, and a thermal conductivity of the resistive switching layer is in a range from 2.2 W/m·K to 5 W/m·K; and
the thermal conductivity of the intermediate layer is in a range from 0.2 W/m·K to 2 W/m·K, and an electrical conductivity of the intermediate layer is in a range from 10⁻⁷ S/m to 10⁻² S/m.

3. The 1S1R-based self-selective memory according to claim 2, wherein a thermal conductivity of a side of the intermediate layer close to the resistive switching layer is lower than that of a side close to the selector layer.

4. The 1S1R-based self-selective memory according to claim 3, wherein the thermal conductivity of the intermediate layer decreases in a direction from the selector layer to the resistive switching layer.

5. The 1S1R-based self-selective memory according to claim 2, wherein a material of the intermediate layer comprises at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

6. The 1S1R-based self-selective memory according to claim 1, wherein a material of the selector layer comprises at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide, or antimony telluride.

7. The 1S1R-based self-selective memory according to claim 1, wherein a material of the resistive switching layer comprises at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

8. The 1S1R-based self-selective memory according to claim 1, wherein the first functional layer is the selector layer, and the second functional layer is the resistive switching layer.

9. The 1S1R-based self-selective memory according to claim 1, wherein a material of the first functional layer comprises niobium oxide, a material of the intermediate layer comprises amorphous carbon, and a material of the second functional layer comprises tantalum oxide.

10. The 1S1R-based self-selective memory according to claim 1, wherein the first functional layer is the resistive switching layer, and the second functional layer is the selector layer; and
a material of the first functional layer comprises tantalum oxide, a material of the intermediate layer comprises amorphous carbon, and a material of the second functional layer comprises niobium oxide.

11. A manufacturing method for a 1S1R-based self-selective memory, comprising:
providing a substrate, and forming a first electrode on the substrate;
forming a first functional layer on the first electrode;
forming an intermediate layer on the first functional layer;
forming a second functional layer on the intermediate layer, wherein the second functional layer is separated from the first functional layer by the intermediate layer, one of the first functional layer and the second functional layer is a selector layer, and the other of the first functional layer and the second functional layer is a resistive switching layer, and a thermal conductivity of the intermediate layer is lower than that of the resistive switching layer; and
forming a second electrode on the second functional layer.

12. The manufacturing method according to claim 11, wherein a thermal conductivity of the selector layer is in a range from 0.3 W/m·K to 1.5 W/m·K, and a thermal conductivity of the resistive switching layer is in a range from 2.2 W/m·K to 5 W/m·K; and
the thermal conductivity of the intermediate layer is in a range from 0.2 W/m·K to 2 W/m·K, and an electrical conductivity of the intermediate layer is in a range from 10⁻⁷ S/m to 10⁻² S/m.

13. The manufacturing method according to claim 12, wherein thermal conductivity of a side of the intermediate layer close to the resistive switching layer is lower than that of a side close to the selector layer.

14. The manufacturing method according to claim 12, wherein the thermal conductivity of the intermediate layer decreases in a direction from the selector layer to the resistive switching layer.

15. The manufacturing method according to claim 12, wherein a material of the intermediate layer comprises at least one of amorphous carbon, silicon carbide, tellurium carbide, tellurium carbon sulfide, molybdenum sulfide, tungsten sulfide, molybdenum telluride, indium gallium zinc oxide, indium aluminum zinc oxide, tin-doped indium oxide, manganese telluride, tungsten telluride, or zinc-doped indium oxide.

16. The manufacturing method according to claim 11, wherein a material of the selector layer comprises at least one of niobium oxide, vanadium oxide, iron oxide, neodymium nickel oxide, samarium nickel oxide, lanthanum cobalt oxide, gadolinium cobalt oxide, germanium telluride, aluminum telluride, boron telluride, germanium selenide, germanium sulfide and antimony telluride; and
a material of the resistive switching layer comprises at least one of tantalum oxide, titanium oxide, hafnium oxide, zirconium oxide, silicon oxide, magnesium oxide, aluminum nitride, germanium antimony telluride, scandium antimony telluride, indium silver antimony telluride, germanium antimonide, germanium telluride, antimony telluride, copper sulfide, germanium sulfide, germanium selenide, zinc sulfide, aluminum borate, strontium titanate, zirconium titanate, barium titanate, hafnium zirconium oxide, or hafnium aluminum oxide.

17. The manufacturing method according to claim 11, after forming the intermediate layer on the first functional layer, further comprising:
ionizing first gas to generate plasma, and processing the intermediate layer with the plasma.

18. The manufacturing method according to claim 11, wherein the first functional layer is the selector layer, and the second functional layer is the resistive switching layer, the material of the first functional layer comprises niobium oxide, a material of the intermediate layer comprises amorphous carbon, and a material of the second functional layer comprises tantalum oxide.

19. The manufacturing method according to claim 11, wherein the first functional layer is the resistive switching layer, the second functional layer is the selector layer, a material of the first functional layer comprises tantalum oxide, a material of the intermediate layer comprises amorphous carbon, and a material of the second functional layer comprises niobium oxide.

20. An electronic device, comprising the 1S1R-based self-selective memory according to claim 1.
